(19) United States
(12) Patent Application Publication
(10) Pub. No.: US 2009/0323985 A1
(43) Pub. Date: Dec. 31, 2009

(54) SYSTEM AND METHOD OF CONTROLLING POWER CONSUMPTION IN RESPONSE TO VOLUME CONTROL

(75) Inventors: Harinath Garudadri, San Diego, CA (US); Somdeb Majumdar, San Diego, CA (US); Jay King, San Diego, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/179,501

(22) Filed: Jul. 24, 2008

Related U.S. Application Data
(60) Provisional application No. 61/077,023, filed on Jun. 30, 2008.

(51) Int. Cl. H03G 3/00

(52) U.S. Cl. 381/104

(57) ABSTRACT

An apparatus for audio processing including a first device (e.g., a multiplier, digital signal gain module, etc.) adapted to apply a gain to a first digital audio signal to generate a second digital audio signal; a second device (e.g., a digital-to-analog converter (DAC), etc.) adapted to generate an analog audio signal from the second digital audio signal; a third device (e.g., a detector, sensor, user interface, etc.) adapted to generate an audio characteristic signal related to a characteristic of the first or second digital audio signal, or the analog audio signal; and a fourth device (e.g., a controller, control module, etc.) adapted to control the gain of the first device based on a first function of the audio characteristic signal, and control a power supplied to the second device based on a second function of the audio characteristic signal.

### CROSS-REFERENCE TO A RELATED APPLICATION

The present Application for Patent claims priority to Provisional Application No. 61/077,023 entitled “SYSTEM AND METHOD OF CONTROLLING POWER CONSUMPTION IN RESPONSE TO VOLUME CONTROL” filed Jun. 30, 2008, and hereby expressly incorporated by reference herein.

### FIELD

The present disclosure relates generally to audio and communications systems, and more specifically, to a system and method of controlling power consumption in an audio and/or communications system in response to volume control.

### BACKGROUND

Many audio devices currently being developed are portable and configured in a relatively compact manner. Because of their portability, audio devices typically derive power from limited power sources, such as batteries. Since the power from such sources are limited, the continuous use of the devices depends on the amount of power being consumed. Accordingly, these audio devices are typically designed to consume power efficiently.

An exemplary method of configuring an audio device for better power efficient operation is to vary the supply voltage of the output audio stage with the level of the output audio signal. In this configuration, the supply voltage is usually varied to be slightly larger than the peak-to-peak swing of the output audio signal. However, if the level of the audio signal is relatively smaller, the supply voltage may fall below the minimum supply voltage for operating the active devices of the audio output stage. If such is the case, the supply voltage for the audio output stage may no longer be capable of controlling the level of the output audio signal.

### SUMMARY

An aspect of the disclosure relates to an apparatus for signal processing. The apparatus comprises a first device adapted to apply a gain to a first digital signal to generate a second digital signal; a second device adapted to generate an analog signal from the second digital signal; a third device adapted to generate a characteristic signal related to a characteristic of the first or second digital signal, or the analog signal; and a fourth device adapted to control the gain of the first device based on a first function of the characteristic signal, and control a power supplied to the second device based on a second function of the characteristic signal. In another aspect, the first and second digital signals respectively comprise first and second digital audio signals, and the analog signal comprises an analog audio signal.

In another aspect, the third device comprises a volume control module adapted to generate an audio characteristic signal related to the volume level setting. In another aspect, the first function comprises maintaining the gain substantially constant if the volume level signal is above a threshold volume level, and changing the gain if the volume level signal is below the threshold volume level. In another aspect, the changing of the gain comprises increasing the gain with increasing volume level. In another aspect, the second function comprises maintaining the power supplied to the second device substantially constant if the volume level signal is below the threshold volume level, and changing the power supplied to the second device if the volume level signal is above the threshold volume level. In another aspect, the changing of the power supplied to the second device comprises increasing the power supplied to the second device with increasing volume level.

In yet another aspect, the third device comprises a detector for sensing the characteristic related to the first or second digital signal. In another aspect, the characteristic related to the first or second digital signal comprises an envelope, average, root mean square (RMS) or energy of the first or second digital signal. In another aspect, a receiver is adapted to receive a radio frequency (RF) signal from which the first digital signal is derived. In another aspect, the receiver may be configured to receive a signal having a fractional spectrum on the order of 20% or more, a spectrum on the order of 500 MHz or more, or a fractional spectrum on the order of 20% or more and a spectrum on the order of 500 MHz or more.

In other aspects, the first device comprises a multiplier or digital signal gain module, the second device comprises a digital-to-analog converter (DAC), the third device comprises a detector, sensor, or volume level control module, and the fourth device comprises a controller or control module.

Other aspects, advantages and novel features of the present disclosure will become apparent from the following detailed description of the disclosure when considered in conjunction with the accompanying drawings.

### BRIEF DESCRIPTION OF THE DRAWINGS

FIG. 1A illustrates a block diagram of an exemplary audio system in accordance with an aspect of the disclosure.

FIG. 1B illustrates an exemplary graph of a gain for a digital section and power supply voltage for a digital-to-analog (DAC) converter of the exemplary audio system in accordance with another aspect of the disclosure.

FIG. 2 illustrates a block diagram of another exemplary audio system in accordance with another aspect of the disclosure.

FIG. 3 illustrates a block diagram of yet another exemplary audio system in accordance with another aspect of the disclosure.

FIG. 4 illustrates a block diagram of still another exemplary audio system in accordance with another aspect of the disclosure.

FIG. 5 illustrates a block diagram of an exemplary communications device in accordance with another aspect of the disclosure.

FIG. 6 illustrates a block diagram of another exemplary communications device in accordance with another aspect of the disclosure.

FIGS. 7A-D illustrate timing diagrams of various pulse modulation techniques in accordance with another aspect of the disclosure.

FIG. 8 illustrates a block diagram of various communications devices communicating with each other via various channels in accordance with another aspect of the disclosure.

### DETAILED DESCRIPTION

Various aspects of the disclosure are described below. It should be apparent that the teachings herein may be embodied in a wide variety of forms and that any specific structure, function, or both being disclosed herein are merely representative. Based on the teachings herein one skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein.

As an example of some of the above concepts, in some aspects, the disclosure relates to an apparatus for audio processing comprising a first device (e.g., a multiplier, digital signal gain module, etc.) adapted to apply a gain to a first digital audio signal to generate a second digital audio signal; a second device (e.g., a digital-to-analog converter (DAC), etc.) adapted to generate an analog audio signal from the second digital audio signal; a third device (e.g., a detector, sensor, user interface, etc.) adapted to generate an audio characteristic signal related to a characteristic of the first or second digital audio signal, or the analog audio signal; and a fourth device (e.g., a controller, control module, etc.) adapted to control the gain of the first device based on a first function of the audio characteristic signal, and control a power supplied to the second device based on a second function of the audio characteristic signal. The figures below illustrate one aspect of the invention, i.e., the “audio” aspect. However, it shall be understood that the signals processed by the systems described herein need not be limited to audio.

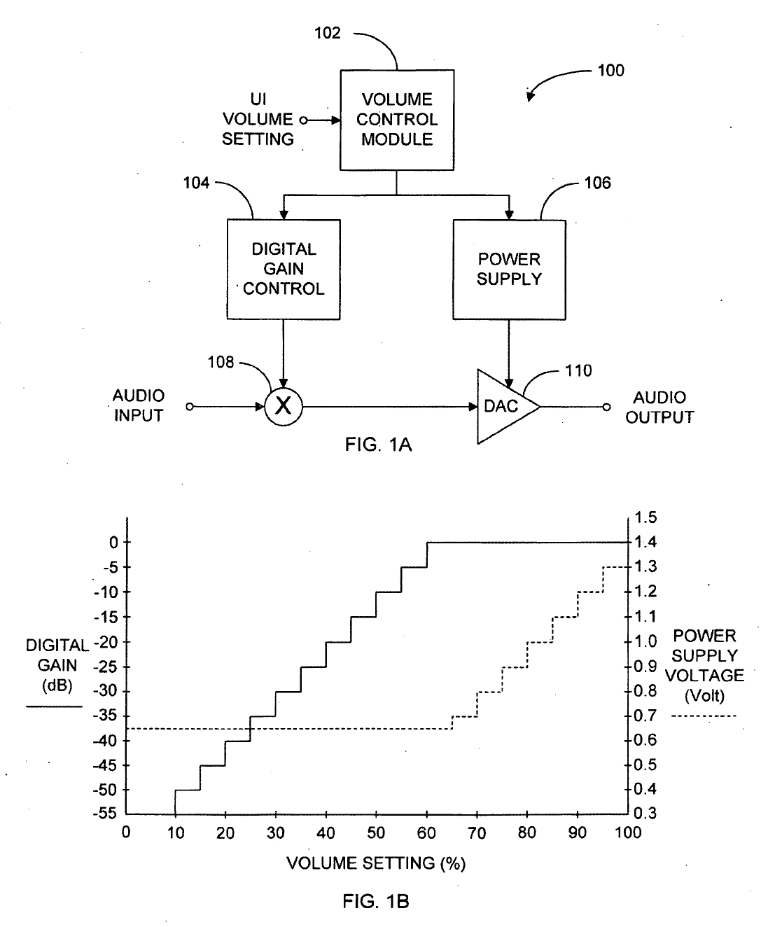

FIG. 1A illustrates a block diagram of an exemplary audio system 100 in accordance with an aspect of the disclosure. In summary, the audio system 100 increases the supply voltage for an analog audio stage (e.g., a digital-to-analog converter (DAC)) with increasing volume level above a defined volume level threshold to achieve a relatively high efficiency in power usage, but maintains the supply voltage substantially constant at below the defined volume level threshold to maintain the one or more active devices in the analog audio stage operating properly. The power supply voltage above the volume level threshold serves to control the volume of the generated sound in response to a volume level signal generated by a volume control module.

Additionally, the audio system 100 increases the gain of a digital stage (e.g., a multiplier) with increasing volume level below the defined volume level threshold, but maintains the gain substantially constant at above the defined volume level threshold. The digital gain below the volume level threshold serves to control the volume of the generated sound in response to the volume level signal generated by the volume control module.

In particular, the audio system 100 comprises a volume control module 102, a digital gain control 104, a power supply 106, a multiplier 108, and a DAC 110. A first digital audio signal is applied to a first input of the multiplier 108, a second digital audio signal is generated at the output of the multiplier 108 (or input of the DAC 110), and an analog audio signal is generated at the output of the DAC 110. The volume control module 102 generates a volume level signal in response to a selected volume level setting from a user interface (UI). The digital gain control 104 generates a gain factor for the multiplier 108 in response to the volume level signal generated by the volume control module 102. The power supply 106 generates a power supply voltage for the DAC 110 in response to the volume level signal generated by the volume control module 102.

The multiplier 108 multiplies the first digital audio signal with the gain factor generated by the digital gain control 104 in order to generate the second digital audio signal. The DAC 110, in turn, converts the second digital audio signal into the analog audio signal. Although not shown, a transducer, such as a speaker, may be coupled to the output of the DAC 110 to generate sound based on the analog audio signal.

As further explained later herein, below a defined volume level threshold, the digital gain control 104 increases the gain factor with increasing volume level signal in order to control the volume of the sound generated by the audio system 100. Also, below the defined volume level threshold, the power supply 106 maintains the supply voltage for the DAC 110 substantially constant and at a level sufficient to maintain the one or more active devices of the DAC 110 operating properly. At above the defined volume level threshold, the digital gain control 104 maintains the gain factor for the multiplier 108 substantially constant. Additionally, at above the defined volume level threshold, the power supply 106 increases the supply voltage for the DAC 110 in order to control the volume of the sound generated by the audio system 100. The following example serves to better explain these concepts.

FIG. 1B illustrates a graph of exemplary digital gain factor and power supply voltage versus volume setting in accordance with another aspect of the disclosure. The y- or vertical axis associated with the solid line response represents the digital gain factor in decibels (dB) generated by the digital gain control 104. The y- or vertical axis associated with the dashed line response represents the power supply voltage in Volt generated by the power supply 106. The x- or horizontal axis represents the volume setting in percentage as received by the volume control module 102, wherein a zero (0) percent volume setting means minimum volume setting and a 100 percent volume setting means maximum volume setting. In this example, the adjustment resolution of the volume setting is in five (5) percent steps. It shall be understood that the volume setting may be discretely adjusted as shown, or continuously adjusted.

In this example, the defined volume threshold is set to 65 percent. Accordingly, as shown, the digital gain factor as represented by the solid line increases with increasing volume setting from −55 dB at a volume setting of 10 percent to zero (0) dB at a volume setting of 60 percent. This provides control of the volume of the sound generated by the audio system 100 below the 60 percent volume level threshold. Above this threshold, the digital gain factor remains substantially constant at zero (0) dB. Although not illustrated, it shall be understood that the digital gain factor may have positive gain values.

Similarly, the power supply voltage as represented by the dashed line remains substantially constant at 0.65 Volt below a 65 percent volume level threshold in order to maintain the one or more active devices of the DAC 110 operating properly. Above the threshold, the power supply voltage increases with increasing volume setting from 0.65V at a volume setting of 65 percent to 1.3V at a volume setting of 100 percent. This provides control of the volume of the sound generated by the audio system 100 above the 65 percent volume threshold. For improved power usage efficiency, the power supply voltage is maintained a defined margin greater than the peak-to-peak voltage of the analog audio signal. Although in this example, the volume setting threshold of 60 percent for the digital gain is different than the volume setting threshold of 65 percent for the power supply voltage, it shall be understood that they may be set at the same volume setting threshold.

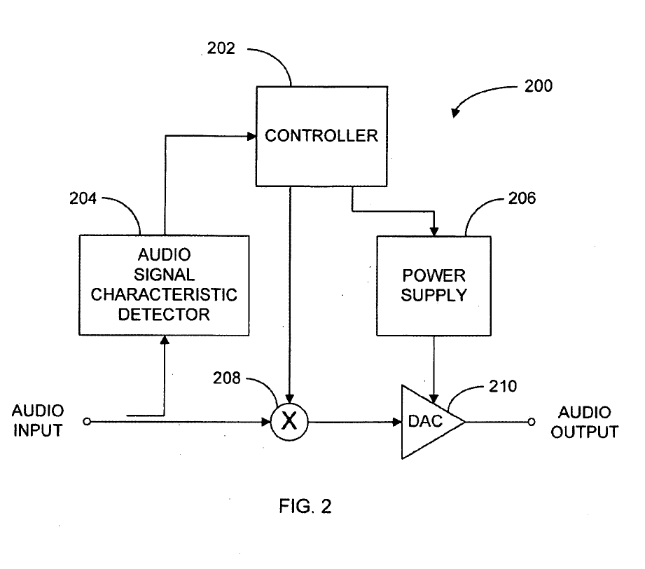

FIG. 2 illustrates a block diagram of another exemplary audio system 200 in accordance with another aspect of the disclosure. In the audio system 100 previously discussed, the gain of the digital section and the power supply voltage of the analog section are varied in response to the user volume setting. The user volume setting is related to the level of the digital and/or analog audio signals generated by the audio system 100. In audio system 200, the gain of the digital section and the power supply voltage of the analog section are varied in response to a direct sensing of a characteristic of at least one of the audio signals. In this example, it is the digital audio signal applied to the input of a multiplier.

In particular, the audio system 200 comprises a controller 202, an audio signal characteristic detector 204, a power supply 206, a multiplier 208, and a DAC 210. A first digital audio signal is applied to a first input of the multiplier 208, a second digital audio signal is generated at the output of the multiplier 208 (or input of the DAC 210), and an analog audio signal is generated at an output of the DAC 210. The audio signal characteristic detector 204 generates an audio characteristic signal related to the first digital audio signal applied to the first input of the multiplier 208. For example, the audio characteristic signal may be related to the envelope, average, root mean square (RMS), or energy of the first digital audio signal.

Based on the audio characteristic signal, the controller 202 generates a gain factor for the multiplier 208 and a control signal for the power supply 206. More specifically, the controller 202 generates a digital gain factor that increases with increasing audio characteristic signal (e.g., with increasing envelope, average, RMS, or energy) below a defined audio characteristic threshold, and maintains the digital gain factor substantially constant above the defined audio characteristic threshold. Additionally, the controller 202 generates a control signal for the power supply 206 such that the power supply voltage remains substantially constant below the defined audio characteristic threshold, and increases with increasing audio characteristic signal (e.g., with increasing envelope, average, RMS, or energy) above the defined audio characteristic threshold.

Similar to the audio system 100, the increasing digital gain with increasing audio characteristic signal provides control of the volume of the sound generated by the audio system 200 below the defined threshold, and the increasing power supply voltage provides control of the volume of the sound generated by the audio system 200 above the defined threshold. Again, for improved power usage efficiency, the power supply voltage is maintained a defined margin greater than the peak-to-peak voltage of the analog audio signal. Although, in this example, the audio signal characteristic detector 204 is configured to sense or detect a characteristic of the digital audio signal at the input of the multiplier 208, it shall be understood that the detector 204 may be configured to sense or detect a characteristic of any other audio signal in the audio system 200, such as the digital audio signal at the output of the multiplier 208 (or input of the DAC 210) or the output of the DAC 210.

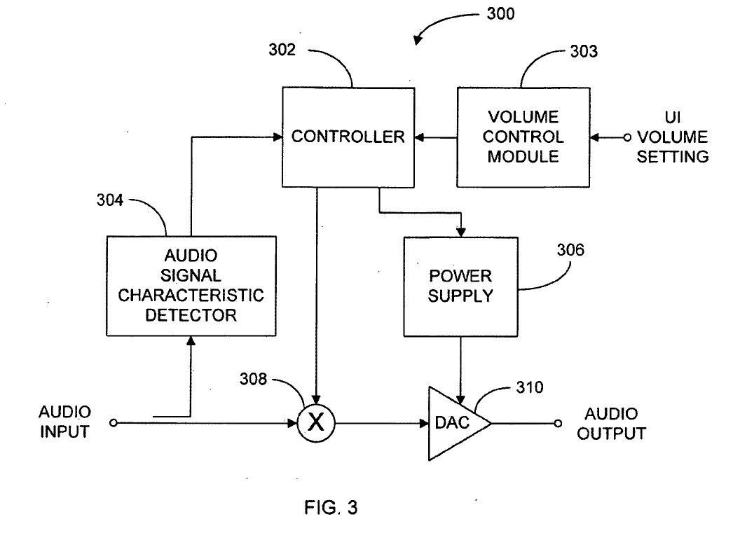

FIG. 3 illustrates a block diagram of yet another exemplary audio system 300 in accordance with another aspect of the disclosure. In summary, the audio system 300 include features of both audio systems 100 and 200 to achieve a defined functionality. That is, similar to the audio system 100, the audio system 300 varies the digital gain of the digital section as a first function ƒ₁ of the UI volume setting, and varies the power supply voltage for the analog section as a second function ƒ₂ of the UI volume setting. Similar to the audio system 200, the audio system 300 varies the digital gain of the digital section as a third function ƒ₃ of the sensed or detected characteristic of the digital or analog audio signal of the system 300, and varies the power supply voltage for the analog section as a fourth function ƒ₄ of the sensed or detected characteristic of the digital or analog audio signal of the system 300.

In particular, the audio system 300 comprises a controller 302, a volume control module 303, an audio signal characteristic detector 304, a power supply 306, a multiplier 308, and a DAC 310. A first digital audio signal is applied to the input of the multiplier 308, a second digital audio signal is generated at the output of the multiplier 308 (or input of the DAC 310), and an analog audio signal is generated at the output of the DAC 310. The audio signal characteristic detector 304 generates an audio characteristic signal related to a characteristic of the first digital audio signal applied to the first input of the multiplier 308. For example, the audio characteristic signal may be related to the envelope, average, root mean square (RMS), or energy of the first digital audio signal.

Based on the audio characteristic signal, the controller 302 generates a gain factor for the multiplier 308 and a control signal for the power supply 306. More specifically, the controller 302 generates a digital gain factor that varies as a first function ƒ₁ of the audio characteristic signal generated by the audio signal characteristic detector 304. Also, the controller 302 generates a control signal for the power supply 306 such that the power supply voltage varies as a second function ƒ₂ of the audio characteristic signal. Additionally, the controller 302 varies the digital gain factor as a third function ƒ₃ of the volume level signal generated by the volume control module 303. Also, the controller 302 varies the control signal for the power supply 306 such that the power supply voltage varies as a fourth function ƒ₄ of the volume level signal. The functions ƒ₁₋₄ may be configured to achieve a particular functionality for the audio system 300.

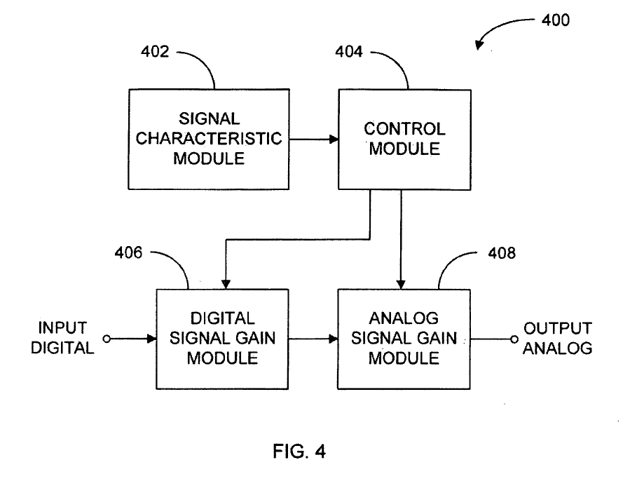

FIG. 4 illustrates a block diagram of still another exemplary signal processing system 400 in accordance with another aspect of the disclosure. The concepts described above may be summarized with reference to the system 400. In particular, the system 400 comprises a signal characteristic module 402, a control module 404, a digital signal gain module 406, and an analog signal gain module 408. A first digital signal is applied to the input of the digital signal gain module 406, a second digital signal is generated at the output of the digital signal gain module 406 (or input of the analog signal gain module 408), and an analog signal is generated at the output of the analog signal gain module 408.

The signal characteristic module 402 generates a signal related to a characteristic of a signal processed by the audio system 400. As previously discussed, examples of signal characteristics include volume setting or level, envelope, average, root mean square (RMS), or energy of the signal. The control module 404, in turn, generates a first control signal to vary the gain of the digital signal gain module 406 as a first function of the signal generated by the signal characteristic module 402. The control module 404 also generates a second control signal to vary the power supplied to the analog signal gain module 408 as a second function of the signal generated by the signal characteristic module 402. The first and second functions may be configured to achieve a particular functionality for the system 400.

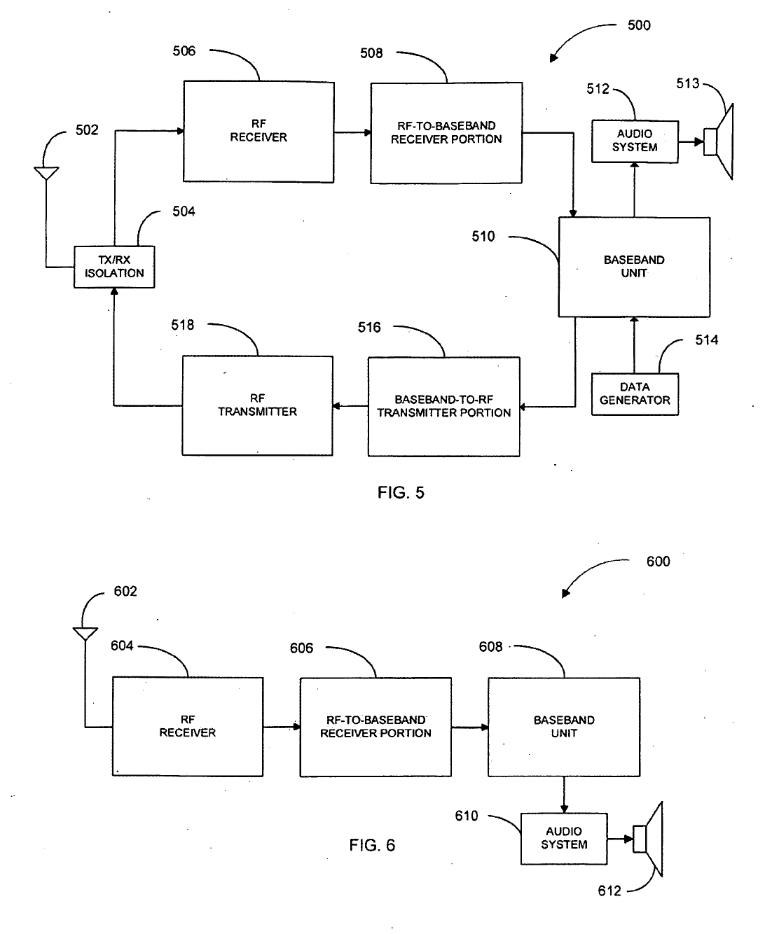

FIG. 5 illustrates a block diagram of an exemplary communications device 500 including an exemplary audio system in accordance with another aspect of the disclosure. The communications device 500 may be particularly suited for sending and receiving data to and from other communications devices. The communications device 500 comprises an antenna 502, a Tx/Rx isolation device 504, a front-end receiver portion 506, an RF-to-baseband receiver portion 508, a baseband unit 510, an audio system 512, a speaker 513, a data generator 514, a baseband-to-RF transmitter portion 516, and an RF transmitter 518. The audio system 512 may be configured to include any of the features, concepts, and aspects of the audio systems 100, 200, 300, and 400 previously discussed.

In operation, the audio system 512 may receive audio data from a remote communications device via the antenna 502 which picks up the RF signal from the remote communications device, the Tx/Rx isolation device 504 which sends the signal to the front-end receiver portion 506, the receiver front-end 506 which amplifies the received signal, the RF-to-baseband receiver portion 508 which converts the RF signal into a baseband signal, and the baseband unit 510 which processes the baseband signal to determine the received audio data. The audio system 512 generates an analog audio signal for the speaker 513 based on the received audio data.

Further, in operation, the data generator 514 may generate outgoing data for transmission to another communications device via the baseband unit 510 which processes the outgoing data into a baseband signal for transmission, the baseband-to-RF transmitter portion 516 which converts the baseband signal into an RF signal, the transmitter 518 which conditions the RF signal for transmission via the wireless medium, the Tx/Rx isolation device 504 which routes the RF signal to the antenna 502 while isolating the input of the receiver front-end 506, and the antenna 502 which radiates the RF signal to the wireless medium. The data generator 514 may be a sensor or other type of data generator. For example, the data generator 518 may include a microprocessor, a microcontroller, a RISC processor, a keyboard, a pointing device such as a mouse or a track ball, an audio device, such as a headset, including a transducer such as a microphone, a medical device, a shoe, a robotic or mechanical device that generates data, a user interface, such as a display, one or more light emitting diodes (LED), etc.

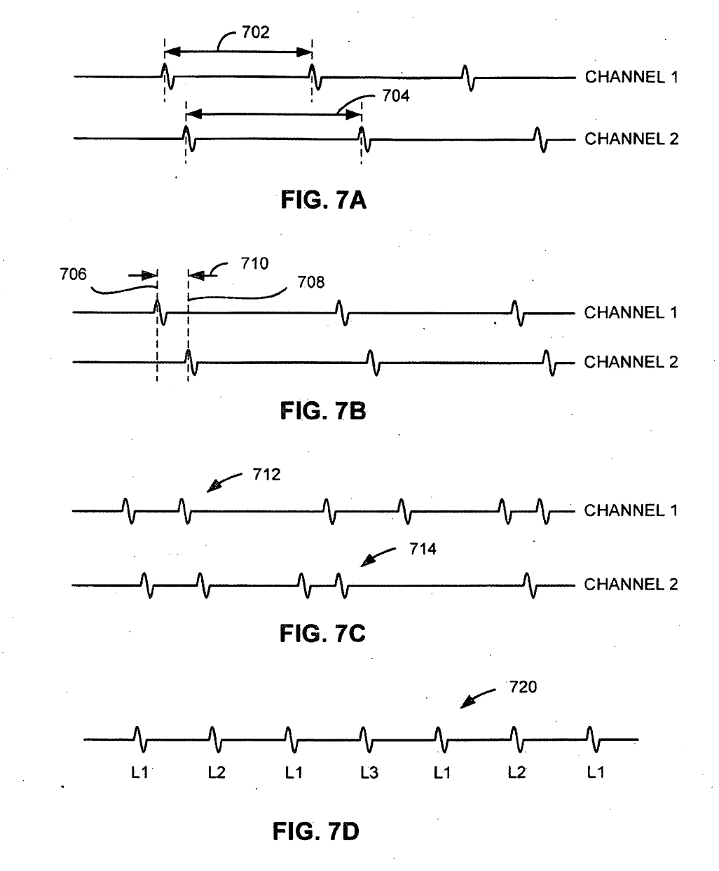

FIG. 6 illustrates a block diagram of an exemplary communications device 600 including an exemplary audio system in accordance with another aspect of the disclosure. The communications device 600 may be particularly suited for receiving audio data from other communications devices. The communications device 600 comprises an antenna 602, a front-end receiver 604, an RF-to-baseband receiver portion 606, a baseband unit 608, an audio system 610, and a speaker 612. The audio system 610 may be configured to include any of the features, concepts, and aspects of the audio systems 100, 200, 300, and 400 previously discussed.

In operation, the audio system 610 may receive audio data from a remote communications device via the antenna 602 which picks up the RF signal from the remote communications device, the receiver front-end 604 which amplifies the received signal, the RF-to-baseband receiver portion 606 which converts the RF signal into a baseband signal, and the baseband unit 608 which processes the baseband signal to determine the received audio data. The audio system 512 generates an analog audio signal for the speaker 513 based on the received audio data. The communications device 600 may be configured to include a microprocessor, a microcontroller, a reduced instruction set computer (RISC) processor, a display, an audio device, such as a headset, including a transducer such as speakers, a medical device, a shoe, a watch, a robotic or mechanical device responsive to the data, a user interface, such as a display, one or more light emitting diodes (LED), etc.

FIG. 7A illustrates different channels (channels 1 and 2) defined with different pulse repetition frequencies (PRF) as an example of a pulse modulation that may be employed in any of the communications systems described herein. Specifically, pulses for channel 1 have a pulse repetition frequency (PRF) corresponding to a pulse-to-pulse delay period 702. Conversely, pulses for channel 2 have a pulse repetition frequency (PRF) corresponding to a pulse-to-pulse delay period 704. This technique may thus be used to define pseudo-orthogonal channels with a relatively low likelihood of pulse collisions between the two channels. In particular, a low likelihood of pulse collisions may be achieved through the use of a low duty cycle for the pulses. For example, through appropriate selection of the pulse repetition frequencies (PRF), substantially all pulses for a given channel may be transmitted at different times than pulses for any other channel.

The pulse repetition frequency (PRF) defined for a given channel may depend on the data rate or rates supported by that channel. For example, a channel supporting very low data rates (e.g., on the order of a few kilobits per second or Kbps) may employ a corresponding low pulse repetition frequency (PRF)). Conversely, a channel supporting relatively high data rates (e.g., on the order of a several megabits per second or Mbps) may employ a correspondingly higher pulse repetition frequency (PRF).

FIG. 7B illustrates different channels (channels 1 and 2) defined with different pulse positions or offsets as an example of a modulation that may be employed in any of the communications systems described herein. Pulses for channel 1 are generated at a point in time as represented by line 706 in accordance with a first pulse offset (e.g., with respect to a given point in time, not shown). Conversely, pulses for channel 2 are generated at a point in time as represented by line 708 in accordance with a second pulse offset. Given the pulse offset difference between the pulses (as represented by the arrows 710), this technique may be used to reduce the likelihood of pulse collisions between the two channels. Depending on any other signaling parameters that are defined for the channels (e.g., as discussed herein) and the precision of the timing between the devices (e.g., relative clock drift), the use of different pulse offsets may be used to provide orthogonal or pseudo-orthogonal channels.

FIG. 7C illustrates different channels (channels 1 and 2) defined with different timing hopping sequences modulation that may be employed in any of the communications systems described herein. For example, pulses 712 for channel 1 may be generated at times in accordance with one time hopping sequence while pulses 714 for channel 2 may be generated at times in accordance with another time hopping sequence. Depending on the specific sequences used and the precision of the timing between the devices, this technique may be used to provide orthogonal or pseudo-orthogonal channels. For example, the time hopped pulse positions may not be periodic to reduce the possibility of repeat pulse collisions from neighboring channels.

FIG. 7D illustrates different channels defined with different time slots as an example of a pulse modulation that may be employed in any of the communications systems described herein. Pulses for channel L1 are generated at particular time instances. Similarly, pulses for channel L2 are generated at other time instances. In the same manner, pulse for channel L3 are generated at still other time instances. Generally, the time instances pertaining to the different channels do not coincide or may be orthogonal to reduce or eliminate interference between the various channels.

It should be appreciated that other techniques may be used to define channels in accordance with a pulse modulation schemes. For example, a channel may be defined based on different spreading pseudo-random number sequences, or some other suitable parameter or parameters. Moreover, a channel may be defined based on a combination of two or more parameters.

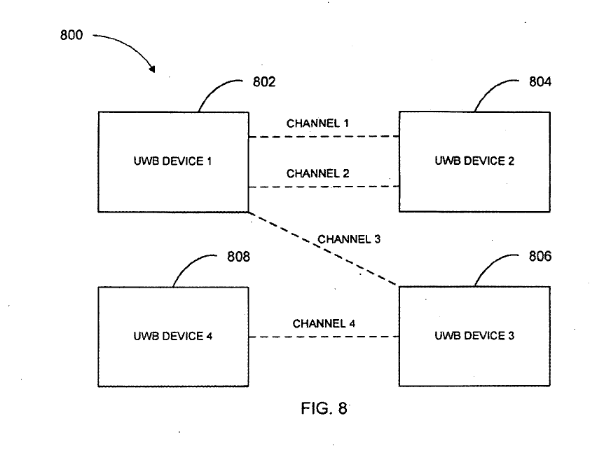

FIG. 8 illustrates a block diagram of various ultra-wide band (UWB) communications devices communicating with each other via various channels in accordance with another aspect of the disclosure. For example, UWB device 1 802 is communicating with UWB device 2 804 via two concurrent UWB channels 1 and 2. UWB device 802 is communicating with UWB device 3 806 via a single channel 3. And, UWB device 3 806 is, in turn, communicating with UWB device 4 808 via a single channel 4. Other configurations are possible. The communications devices may be used for many different applications, and may be implemented, for example, in a headset, microphone, biometric sensor, heart rate monitor, pedometer, EKG device, watch, shoe, remote control, switch, tire pressure monitor, or other communications devices. A medical device may include smart band-aid, sensors, vital sign monitors, and others. The communications devices described herein may be used in any type of sensing application, such as for sensing automotive, athletic, and physiological (medical) responses.

Any of the above aspects of the disclosure may be implemented in many different devices. For example, in addition to medical applications as discussed above, the aspects of the disclosure may be applied to health and fitness applications. Additionally, the aspects of the disclosure may be implemented in shoes for different types of applications. There are other multitude of applications that may incorporate any aspect of the disclosure as described herein.

Various aspects of the disclosure have been described above. It should be apparent that the teachings herein may be embodied in a wide variety of forms and that any specific structure, function, or both being disclosed herein is merely representative. Based on the teachings herein one skilled in the art should appreciate that an aspect disclosed herein may be implemented independently of any other aspects and that two or more of these aspects may be combined in various ways. For example, an apparatus may be implemented or a method may be practiced using any number of the aspects set forth herein. In addition, such an apparatus may be implemented or such a method may be practiced using other structure, functionality, or structure and functionality in addition to or other than one or more of the aspects set forth herein. As an example of some of the above concepts, in some aspects concurrent channels may be established based on pulse repetition frequencies. In some aspects concurrent channels may be established based on pulse position or offsets. In some aspects concurrent channels may be established based on time hopping sequences. In some aspects concurrent channels may be established based on pulse repetition frequencies, pulse positions or offsets, and time hopping sequences.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, processors, means, circuits, and algorithm steps described in connection with the aspects disclosed herein may be implemented as electronic hardware (e.g., a digital implementation, an analog implementation, or a combination of the two, which may be designed using source coding or some other technique), various forms of program or design code incorporating instructions (which may be referred to herein, for convenience, as “software” or a “software module”), or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented within or performed by an integrated circuit (“IC”), an access terminal, or an access point. The IC may comprise a general purpose processor, a digital signal processor (DSP), an application specific integrated circuit (ASIC), a field programmable gate array (FPGA) or other programmable logic device, discrete gate or transistor logic, discrete hardware components, electrical components, optical components, mechanical components, or any combination thereof designed to perform the functions described herein, and may execute codes or instructions that reside within the IC, outside of the IC, or both. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

It is understood that any specific order or hierarchy of steps in any disclosed process is an example of a sample approach. Based upon design preferences, it is understood that the specific order or hierarchy of steps in the processes may be rearranged while remaining within the scope of the present disclosure. The accompanying method claims present elements of the various steps in a sample order, and are not meant to be limited to the specific order or hierarchy presented.

The steps of a method or algorithm described in connection with the aspects disclosed herein may be embodied directly in hardware, in a software module executed by a processor, or in a combination of the two. A software module (e.g., including executable instructions and related data) and other data may reside in a data memory such as RAM memory, flash memory, ROM memory, EPROM memory, EEPROM memory, registers, a hard disk, a removable disk, a CD-ROM, or any other form of computer-readable storage medium known in the art. A sample storage medium may be coupled to a machine such as, for example, a computer/processor (which may be referred to herein, for convenience, as a “processor”) such the processor can read information (e.g., code) from and write information to the storage medium. A sample storage medium may be integral to the processor. The processor and the storage medium may reside in an ASIC. The ASIC may reside in user equipment. In the alternative, the processor and the storage medium may reside as discrete components in user equipment. Moreover, in some aspects any suitable computer-program product may comprise a computer-readable medium comprising codes relating to one or more of the aspects of the disclosure. In some aspects a computer program product may comprise packaging materials.

While the invention has been described in connection with various aspects, it will be understood that the invention is capable of further modifications. This application is intended to cover any variations, uses or adaptation of the invention following, in general, the principles of the invention, and including such departures from the present disclosure as come within the known and customary practice within the art to which the invention pertains.

What is claimed is:

1. An apparatus for signal processing, comprising:
a first device adapted to apply a gain to a first digital signal to generate a second digital signal;
a second device adapted to generate an analog signal from the second digital signal;
a third device adapted to generate a characteristic signal related to a characteristic of the first or second digital signal, or the analog signal; and
a fourth device adapted to:
control the gain of the first device based on a first function of the characteristic signal; and
control a power supplied to the second device based on a second function of the characteristic signal.

2. The apparatus of claim 1, wherein the first and second digital signal respectively comprise first and second digital audio signals, and further wherein the analog signal comprises an analog audio signal.

3. The apparatus of claim 2, wherein the third device comprises a control module, and further wherein the characteristic signal comprises a volume level signal.

4. The apparatus of claim 3, wherein the first function comprises:
maintaining the gain substantially constant if the volume level signal is above a threshold volume level; and
changing the gain if the volume level signal is below the threshold volume level.

5. The apparatus of claim 4, wherein changing the gain comprises increasing the gain with increasing volume level.

6. The apparatus of claim 3, wherein the second function comprises:
maintaining the power supplied to the second device substantially constant if the volume level signal is below a threshold volume level; and
changing the power supplied to the second device if the volume level signal is above the threshold volume level.

7. The apparatus of claim 6, wherein changing the power supplied to the second device comprises increasing the power supplied to the second device with increasing volume level.

8. The apparatus of claim 1, wherein the third device comprises a detector for sensing the characteristic related to the first or second digital signal.

9. The apparatus of claim 8, wherein the characteristic related to the first or second digital signal comprises an envelope, average, root mean square (RMS), or energy of the first or second digital signal.

10. The apparatus of claim 1, further comprising a receiver adapted to receive a radio frequency (RF) signal from which said first digital signal is derived.

11. The apparatus of claim 1, wherein the first device comprises a multiplier or a digital signal gain module.

12. The apparatus of claim 1, wherein the second device comprises a digital-to-analog converter (DAC).

13. The apparatus of claim 1, wherein the fourth device comprises a volume control module, a controller, or a control module.

14. A method of processing signals, comprising:
applying a gain to a first digital signal to generate a second digital signal;
generating an analog signal from the second digital signal;
generating a characteristic signal indicative of a characteristic related to the first or second digital signal, or the analog signal;
controlling the gain applied to the first digital signal based on a first function of the characteristic signal; and
controlling a power supplied in generating the analog signal based on a second function of the characteristic signal.

15. The method of claim 14, wherein the first and second digital signal respectively comprise first and second digital audio signals, and further wherein the analog signal comprises an analog audio signal.

16. The method of claim 15, wherein the characteristic signal comprises a volume level signal.

17. The method of claim 16, wherein the first function comprises:
maintaining the gain substantially constant if the volume level signal is above a threshold volume level; and
changing the gain if the volume level signal is below the threshold volume level.

18. The method of claim 17, wherein changing the gain comprises increasing the gain with increasing volume level.

19. The method of claim 16, wherein the second function comprises:
maintaining the power supplied in generating the analog audio signal substantially constant if the volume level signal is below a threshold volume level; and
changing the power supplied in generating the analog audio signal if the volume level signal is above the threshold volume level.

20. The method of claim 19, wherein changing the power supplied in generating the analog audio signal comprises increasing the power with increasing volume level.

21. The method of claim 14, wherein generating the characteristic signal comprises sensing the characteristic related to the first or second digital signal.

22. The method of claim 21, wherein the characteristic related to the first or second digital signal comprises an envelope, average, root mean square (RMS), or energy of the first or second digital signal.

23. The method of claim 14, further comprising receiving a radio frequency (RF) signal from which said first digital signal is derived.

24. An apparatus for signal processing, comprising:
means for applying a gain to a first digital signal to generate a second digital signal;
means for generating an analog signal from the second digital signal;
means for generating a characteristic signal related to a characteristic of the first or second digital signal, or the analog signal;
means for controlling the gain applied to the first digital signal based on a first function of the characteristic signal; and
means for controlling a power supplied to the analog signal generating means based on a second function of the characteristic signal.

25. The apparatus of claim 24, wherein the first and second digital signal respectively comprise first and second digital audio signals, and further wherein the analog signal comprises an analog audio signal.

26. The apparatus of claim 25, wherein the characteristic signal generating means comprises a volume control module, and further wherein the characteristic signal comprises a volume level signal.

27. The apparatus of claim 26, wherein the first function comprises:
maintaining the gain substantially constant if the volume level signal is above a threshold volume level; and
changing the gain if the volume level signal is below the threshold volume level.

28. The apparatus of claim 27, wherein changing the gain comprises increasing the gain with increasing volume level.

29. The apparatus of claim 26, wherein the second function comprises:
maintaining the power supplied to the analog signal generating means substantially constant if the volume level signal is below a threshold volume level; and
changing the power supplied to the analog signal generating means if the volume level signal is above the threshold volume level.

30. The apparatus of claim 29, wherein changing the power supplied to the analog signal generating means comprises increasing the power with increasing volume level.

31. The apparatus of claim 24, wherein the characteristic signal generating means comprises means for sensing the characteristic related to the first or second digital signal.

32. The apparatus of claim 31, wherein the characteristic related to the first or second digital signal comprises an envelope, average, root mean square (RMS), or energy of the first or second digital signal.

33. The apparatus of claim 24, further comprising means for receiving a radio frequency (RF) signal from which said first digital signal is derived.

34. The apparatus of claim 24, wherein the gain applying means comprises a multiplier or a digital signal gain module.

35. The apparatus of claim 24, wherein the analog signal generating means comprises a digital-to-analog converter (DAC).

36. The apparatus of claim 24, wherein the gain controlling means comprises a volume control module, a controller, or a control module.

37. A computer readable medium including one or more software modules adapted to:
apply a gain to a first digital signal to generate a second digital signal;
generate an analog signal from the second digital signal;
generate a characteristic signal related to a characteristic of the first or second digital signal, or the analog signal;
control the gain based on a first function of the characteristic signal; and
control a power supplied to generate the analog signal based on a second function of the characteristic signal.

38. A headset, comprising:
a first device adapted to apply a gain to a first digital audio signal to generate a second digital audio signal;
a second device adapted to generate an analog audio signal from the second digital audio signal;
a third device adapted to generate an audio characteristic signal related to a characteristic of the first or second digital audio signal, or the analog audio signal; and
a fourth device adapted to:
control the gain of the first device based on a first function of the audio characteristic signal; and
control a power supplied to the second device based on a second function of the audio characteristic signal; and
a transducer adapted to generate sound from the analog audio signal.

39. A watch, comprising:
a first device adapted to apply a gain to a first digital signal to generate a second digital signal;
a second device adapted to generate an analog signal from the second digital signal;
a third device adapted to generate an characteristic signal related to a characteristic of the first or second digital signal, or the analog signal; and
a fourth device adapted to:
control the gain of the first device based on a first function of the characteristic signal; and
control a power supplied to the second device based on a second function of the characteristic signal; and
a user interface adapted to generate an indication based on the analog signal.

40. A sensing device, comprising:
a digital gain module adapted to apply a gain to a first digital signal to generate a second digital signal;
a digital-to-analog converter (DAC) adapted to generate an analog signal from the second digital signal;
a detector adapted to generate an characteristic signal related to a characteristic of the first or second digital signal, or the analog signal;
a controller adapted to:
control the gain of the digital gain module based on a first function of the characteristic signal; and
control a power supplied to the DAC based on a second function of the characteristic signal; and
a sensor adapted to generate sense data that causes the generation of the first digital signal.
